(19) United States
(12) Patent Application Publication
(10) Pub. No.: US 2006/0255384 A1
(43) Pub. Date: Nov. 16, 2006

(54) Memory device and method of manufacturing the same

(76) Inventors: Peter Baars, Dresden (DE); Klaus Muemmler, Dresden (DE); Daniel Koehler, Chemnitz (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/128,423

(22) Filed: May 13, 2005

(51) Int. Cl. H01L 21/8244; H01L 29/94

(52) U.S. Cl. 257/296; 438/238; 257/308; 257/309; 438/399

(57) ABSTRACT

A memory device includes an array of memory cells and a storage capacitor for storing information. Each memory cell includes an access transistor. The access transistor includes first and second source/drain regions, a channel disposed between the first and the second source/drain regions, and a gate electrode electrically insulated from the channel and adapted to control the conductivity of the channel. The access transistor is at least partially formed in the semiconductor substrate. The storage capacitor is adapted to be accessed by the access transistor. The storage capacitor includes at least first and second storage electrodes and at least a capacitor dielectric disposed between the first and the second storage electrodes. Each of the first and the second storage electrodes is disposed above the substrate surface.

### FIELD OF THE INVENTION

The invention relates to a memory device with an array of memory cells such as DRAM (Dynamic Random Access) memory cells, and to a method of manufacturing such a memory device.

### BACKGROUND

Memory cells of a dynamic random access memory (DRAM) generally comprise a storage capacitor for storing an electrical charge which represents information to be stored, and an access transistor, with is connected to a storage capacitor. The access transistor comprises a first and a second source/drain region, a channel connecting the first and the second source/drain regions, and a gate electrode controlling an electrical current flow between the first and the second source/drain regions. The transistor is usually at least partially formed in the semiconductor substrate. The gate electrode forms part of a word line and is electrically insulated from the channel by a gate dielectric. By addressing the access transistor via a the corresponding word line, the information stored in the storage capacitor is read out to a corresponding bit line.

In the currently used DRAM memory cells, the storage capacitor can be implemented as a trench capacitor in which the two capacitor electrodes are disposed in a trench that extends in the substrate in a direction perpendicular to the substrate surface.

According to another implementation of the DRAM memory cell, the electrical charge is stored in a stacked capacitor formed above the surface of the substrate.

FIG. 21 shows an exemplary view of a memory device includes a memory cell array II and a peripheral portion I. The memory cell array II has a plurality of memory cells 33. Each of the memory cells includes a storage capacitor 24 and an access transistor 30. The storage capacitor includes first and second capacitor electrodes 17, 19. The first capacitor electrode 17 is connected to the first source/drain region 301 of the access transistor. A channel 303 is formed between the first and second source/drain regions 301, 302 and a gate electrode 304 controls the conductivity of the channel 303. The gate electrode is insulated from the channel by a gate insulating layer 305. By addressing the access transistor 30 via the corresponding word line 31, the information stored in the storage capacitor is read out to a corresponding bit line 32. The layout shown in FIG. 21 corresponds to the folded bit line layout. However, the present invention is applicable to any kind of memory cell array layout.

The support portion I refers to a portion at the edge of the memory cell array in which support circuits, such as decoders, sense amplifiers 34, and word line drivers 35 for activating a word line are located. Generally, the peripheral portion of a memory device includes circuitry for addressing memory cells and for sensing and processing the signals received from the individual memory cells.

Usually, the peripheral portion is formed in the same semiconductor substrate as the individual memory cells. Hence, a manufacturing process by which the components of the memory cell array and the peripheral portion can be formed simultaneously is desirable.

In particular, if the storage capacitor of the memory cell is implemented as a stacked capacitor extending above the semiconductor substrate surface, the whole substrate surface is covered by a thick insulating layer, in particular, a silicon dioxide layer. As a consequence, the contacts to the wiring layer in the peripheral portions must be defined to extend across the thick insulating layer. Consequently, the contacts require a high aspect ratio. For providing an electrical contact to the M0 wiring layer, for example, a large landing pad must be provided. Nevertheless, such a large landing pad increases the overall size of the memory device. In addition, the etching rate depends on the size of the contact hole, leading to a further restriction of the process window.

A method of forming a memory device in which bit lines in the array portion are formed simultaneously with landing plugs in the peripheral portion is known. In particular, the landing plugs are formed at a level of the first wiring layer.

### SUMMARY

A memory device includes an array of memory cells, a storage capacitor for storing an information, and a peripheral portion. The memory cells are at least partially formed in a semiconductor substrate having a surface. Each memory cell includes an access transistor having first and second source/drain regions, a channel disposed between the first and second source/drain regions, and a gate electrode electrically insulated from the channel and adapted to control the conductivity of the channel. The access transistor is at least partially formed in the semiconductor substrate. The storage capacitor is adapted to be accessed by the access transistor. The storage capacitor has at least first and second storage electrodes, and at least a capacitor dielectric disposed between the first and second storage electrodes. Each of the first and second storage electrodes is disposed above the substrate surface. A contact between the first storage electrode and the first source/drain region of the access transistor is formed by a capacitor contact and a contact pad. The capacitor contact extends from the substrate surface and connects the substrate surface with the contact pad. The contact pad is adjacent to the first capacitor electrode. The peripheral portion includes peripheral circuitry for controlling a read and a write operation of the memory cell array. The peripheral circuitry is connected with the memory cell array via lines. A first wiring layer is provided in the memory cell array and the peripheral portion. The first wiring layer includes first lines, a contact layer, and a first insulating layer. A contact layer lays above the first wiring layer. The contact layer is provided in the memory cell array and the peripheral portion. A first insulating layer is disposed above the contact layer. The contact layer includes contact pads in the memory cell array. The contact pads are insulated from the first wiring layer. The contact layer includes contact structures in the peripheral portion.

According to a further aspect, the present invention provides a method of forming a memory device that includes providing a semiconductor substrate having a surface, providing an array of access transistors providing a peripheral portion comprising peripheral circuitry, providing a first contact layer including contacts connected with the first source/drain regions, providing a first dielectric layer on the first contact layer, providing a first wiring layer in the array portion and the peripheral portion, providing a first insulating layer in the array portion and the peripheral portion, providing capacitor contact openings in the array portion, providing support contact openings in the peripheral portion, providing a conducting material in the capacitor contact openings and in the support contact openings to from capacitor contacts in the array portion and support contacts in the peripheral portion, providing a second insulating layer on the first insulating layer with the capacitor contacts and the support contacts, defining contact pads in the array portion and contact structures in the peripheral portion, providing a first storage electrode, a storage dielectric, and a second storage electrode, providing a third insulating layer, and forming a contact in the third insulating layer. Each of the access transistors has first and second source/drain regions, a channel disposed between the first and second source/drain regions, and a gate electrode electrically insulated from the channel and adapted to control the conductivity of the channel. Each of access transistors is at least partially formed in the semiconductor substrate. The peripheral portion is at least partially formed in the semiconductor substrate. The contacts are electrically insulated from each other. The first wiring layer includes first lines covered by a wiring insulation layer in the transistor array portion. The first lines of the peripheral portion are uncovered. The material of the insulating layer is different from the wiring insulation layer. The openings contact the contacts of the first contact layer. The support contact openings contact the first lines. The contact pads contact the capacitor contacts and the contact structures contact the support contacts. The first storage electrode contact one of the contact pads, thereby forming a storage capacitor. The contact is connected to one of the contact structures in the peripheral portion.

According to a further aspect, a method of forming a memory device includes providing a semiconductor substrate having a surface, providing an array of access transistors, providing a peripheral portion having peripheral circuitry, providing a first contact layer having contacts connected with the first source/drain regions, providing a first dielectric layer on the first contact layer, providing a first wiring layer in the array portion and the peripheral portion, providing a first insulating layer in the array portion and the peripheral portion, providing capacitor contact openings in the array portion, providing support contact openings in the peripheral portion, providing a conducting material in the capacitor contact openings and in the support contact openings thereby forming contact pads in the array portion and contact structures in the peripheral portion, providing a first storage electrode, a storage dielectric, and a second storage electrode, selectively etching the contact structures in the peripheral portion with respect to wiring insulation layer, selectively etching the wiring insulation layer with respect to the material of the contact structures, and filling the resulting opening with a conductive material to form a contact connected with one of the first liens. Each of the access transistors having first and second source/drain regions, a channel disposed between the first and second source/drain regions, and a gate electrode electrically insulated from the channel and adapted to control the conductivity of the channel. Each of the access transistors is at least partially formed in the semiconductor substrate. The peripheral portion is at least partially formed in the semiconductor substrate. The contacts are electrically insulated from each other. The first wiring layer includes first lines covered by a wiring insulation layer in the transistor array portion and in the peripheral portion. The material of the insulating layer is different from the wiring insulation layer. The support contact openings are adjacent to the wiring insulation layer covering the first lines. The first storage electrode contacts one of the contact pads, thereby forming a storage capacitor. The contact hole is connected to one of the contact structures in the peripheral portion.

In particular, according to the present invention, a memory device has, wherein contact structures lying above the first wiring layer. Accordingly, after covering the semiconductor substrate with a thick insulating layer to cover the storage capacitor, contacts to the first wiring layer are provided by etching, which automatically stops on the contact structures. Thereby, overetching does not occur. Furthermore, since the contact structures are positioned above the wiring layer, contact holes with a relatively smaller aspect ratio of depth to diameter are etched across the thick insulating layer.

In addition, the contact layer in which the contact structures are positioned further includes contact pads in the memory cell array. Accordingly, the contact structures in the peripheral portion and the contact pads in the memory cell array are formed by similar process steps.

In particular, the contact structures in the peripheral portion are connected with the first lines of the first wiring layer, thereby forming landing pads.

In addition, the contact structures are made of a material that can be etched selectively with respect to the material of the first insulating layer.

Furthermore, the memory device of the present invention further includes a second insulating layer disposed above the first wiring layer. The material of the second insulating layer is etched selectively with respect to the material of the contact structures. In this case, the contact structure serves as an etch stop layer.

For example, the contact structures in the peripheral portion can be made of polysilicon or tungsten.

In addition, the landing pads in the peripheral portion have a width of 1.7×F to 2.3×F. The width is measured parallel to the substrate surface. In particular, the contact structures can be relatively large, whereby the overlay requirements of the contact holes to be formed are relatively relaxed.

Moreover, the contact structures forming an etch stop layer in the peripheral portion can have a width 3.5 F to 4 F, largely relaxing the overlay requirements of the contact holes.

In this respect, F refers to the minimum lithographic feature size of the technology used. The minimum-bitline pitch (1 line+1 space) is referred to as 2×F. For example, F can be 110 nm, 90 nm, 60 nm, or even less.

As a consequence, in both cases, the diameter of the contact holes contacting the first wiring layer can be increased whereby a contact resistance is reduced.

In the shown layout, every third line of the first wiring layer is connected with one of the contact structures.

The above and still further objects, features and advantages of the present invention will become apparent upon consideration of the following detailed description of specific embodiments thereof, wherein like numerals designates like components in the drawings.

### BRIEF DESCRIPTION OF THE DRAWINGS

FIGS. 1-10 illustrate steps of manufacturing a memory device according to a first embodiment of the present invention;

FIGS. 11-20 illustrate steps of manufacturing a memory device according to a second embodiment of the present invention; and

FIG. 21 shows a schematic view of a memory device which can be obtained by the method of the present invention.

### DETAILED DESCRIPTION

In the following figures, cross-sectional views of a semiconductor substrate are shown wherein the right hand portion of the figures designates the memory cell array portion II whereas the left hand portion designates the peripheral portion I.

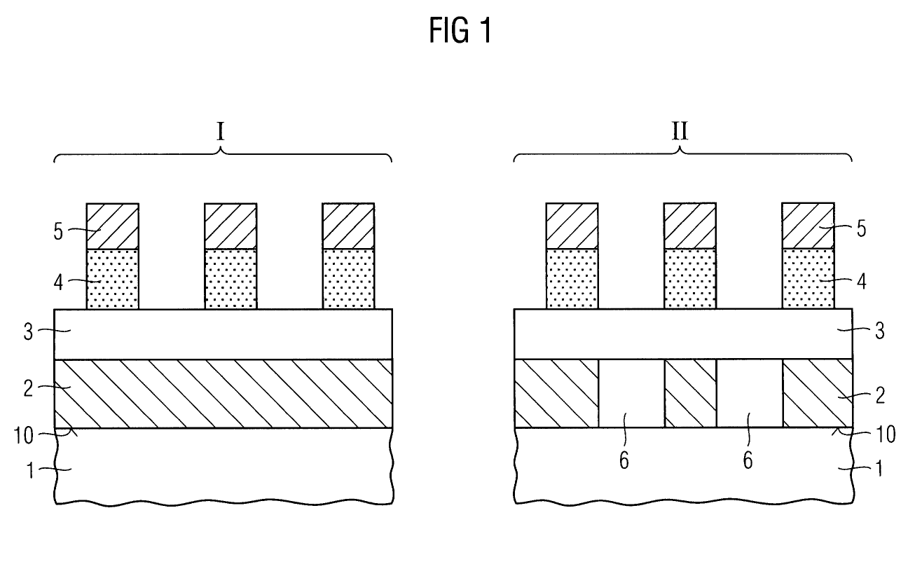

FIG. 1 shows a cross-sectional view of a semiconductor substrate 1, such as a silicon substrate, after processing a transistor array. For processing a transistor array, in particular, first and second source/drain regions are defined in the semiconductor substrate 1 by conducting implantation as is usual. Gate electrodes with a gate insulating layer are provided. In addition, the well implants have been conducted as is usual.

After completing the transistor array, a BPSG (boron phosphorous silicate glass) layer 2 is deposited on the surface 10 of the semiconductor substrate. Subsequently, in the array portion II, contact openings are formed and filled with a conductive material, such as poly-silicon to form poly contacts 6 while maintaining the BPSG layer 2 in the peripheral portion. In the next step, a silicon dioxide layer 3 is deposited on the resulting surface. Thereafter, the lines of the M0 metallization layer 4 are formed as is known in the art.

In particular, the M0 lines 4 can be made of any conductive material and, for example, can be made of tungsten. In the memory cell portion II, the M0 lines or bit lines serve as an interconnect to transfer data between the peripheral portion I and the cell region. In particular, the bit lines are connected with the second source/drain regions of the transistors.

In the peripheral portion I the M0 lines serve as local interconnects. Usually, in the peripheral portion, studs are provided, electrically coupling between the various active devices and transmission lines of the different layers. The conductive M0 lines 4 are covered by a silicon nitride cap layer 5. In FIG. 1, reference numeral II designates a transistor array in the portion of the substrate in which the memory cell array is to be formed, whereas reference numeral I designates the peripheral portion in which the support circuitry is to be formed.

In the next step, the substrate is covered with a mask layer, which is subsequently patterned, for example, photolithographically, so that only the array portion II is covered by the mask layer 7 and the peripheral portion I is uncovered. For example, the mask layer 7 is made of a photoresist material. Thereafter, an anisotropic nitride plasma etching having a high selectivity with respect to silicon dioxide is performed. As a consequence, the silicon nitride layer 5 is removed from the M0 wiring layer 4 in the peripheral portion I.

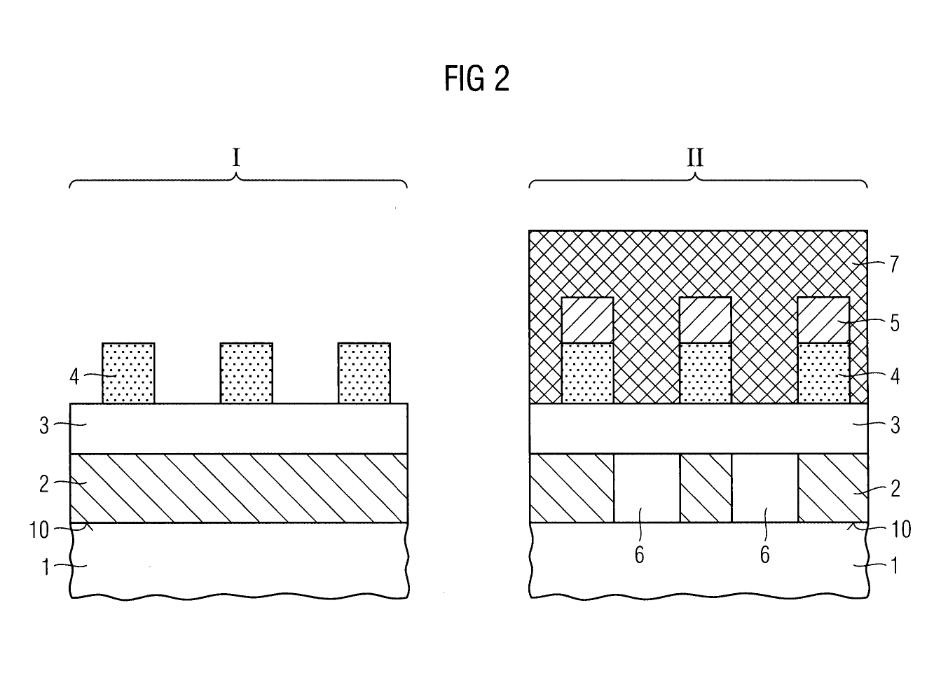

The resulting structure is shown in FIG. 2.

In the next step, the mask layer is removed from the array portion II. Thereafter, a first silicon nitride spacer 8 is formed, as is conventional. In particular, a silicon nitride layer having a thickness of approximately 5 to 10 mm is conformally deposited. Thereafter, an anisotropic etching removes the silicon nitride layer from the horizontal portions of the semiconductor substrate.

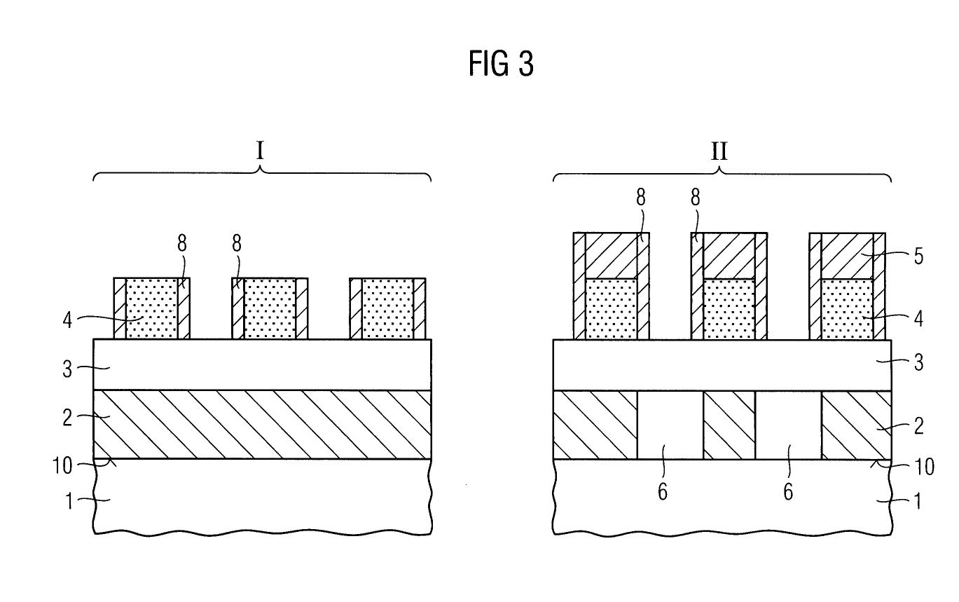

The resulting structure is shown in FIG. 3. As can be seen from FIG. 3, in the array portion II and the peripheral portion I, the lines of the M0 wiring layer are laterally protected by a silicon nitride spacer 8 having a thickness of 5 to 10 mm.

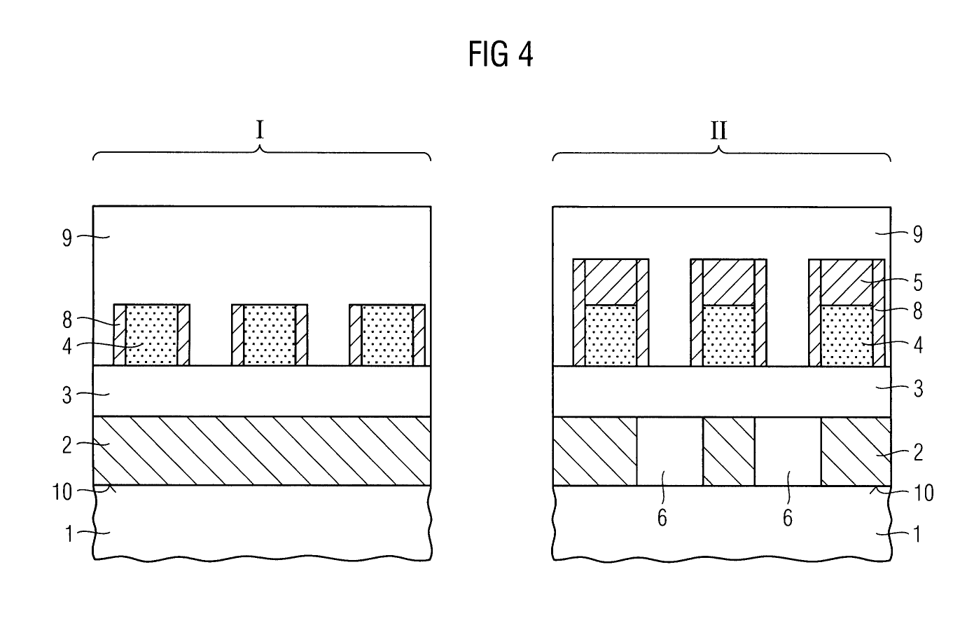

In the next step, a silicon dioxide layer 9 is formed, for example, by a HDP (High Density Plasma) method. Thereafter, a chemical mechanical polishing (CMP) planarizes the silicon dioxide layer so that a small remaining difference in topology between the array II and the peripheral I portion is not critical for the lithographic steps to follow. The resulting structure is shown in FIG. 4.

The CMP step can be performed to stop on the silicon nitride cap 5 in the array portion or to stop in the silicon dioxide layer 9 leaving some 10 to 100 nm silicon dioxide over the silicon nitride cap 5. Optionally, a further silicon dioxide layer can be deposited if a higher thickness of the silicon dioxide layer is wanted for further processing.

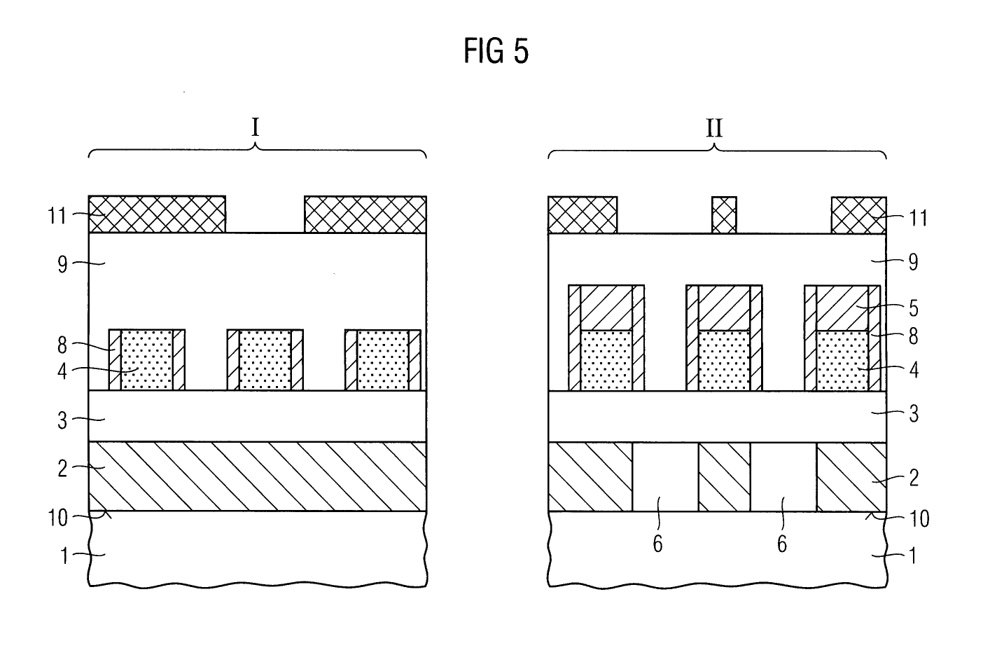

In the next step, a hard mask layer 11 is deposited and patterned using an appropriate mask. The hard mask layer 11, for example, is made of polysilicon. The resulting structure is shown in FIG. 5. Instead of using a hard mask 11, photoresist can be used as a mask for the following etch step.

In the next step, the silicon dioxide layer 9 is etched anisotropically to form capacitor contact openings 25 in the array portion II and support contact openings 26 in the peripheral portion I. For example, patterning the hard mask layer 11, shown with respect to FIG. 5, is performed using one mask for simultaneously patterning the array portion II and the peripheral portion I. During this step, by choosing the width of the lines of the M0 metallization layer adequately, overlay problems can be avoided.

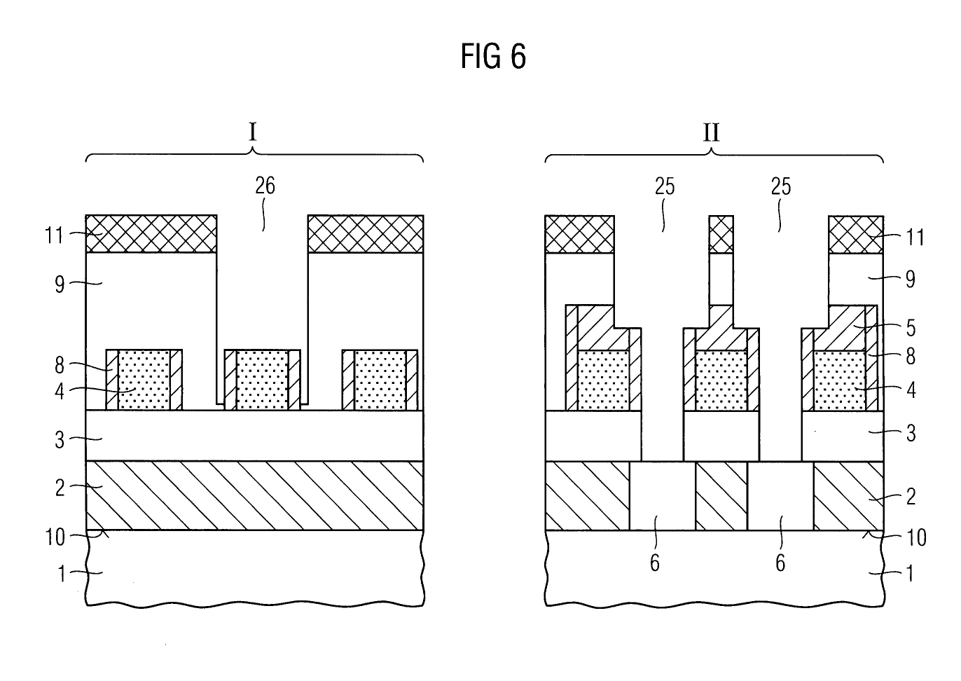

The resulting structure is shown in FIG. 6.

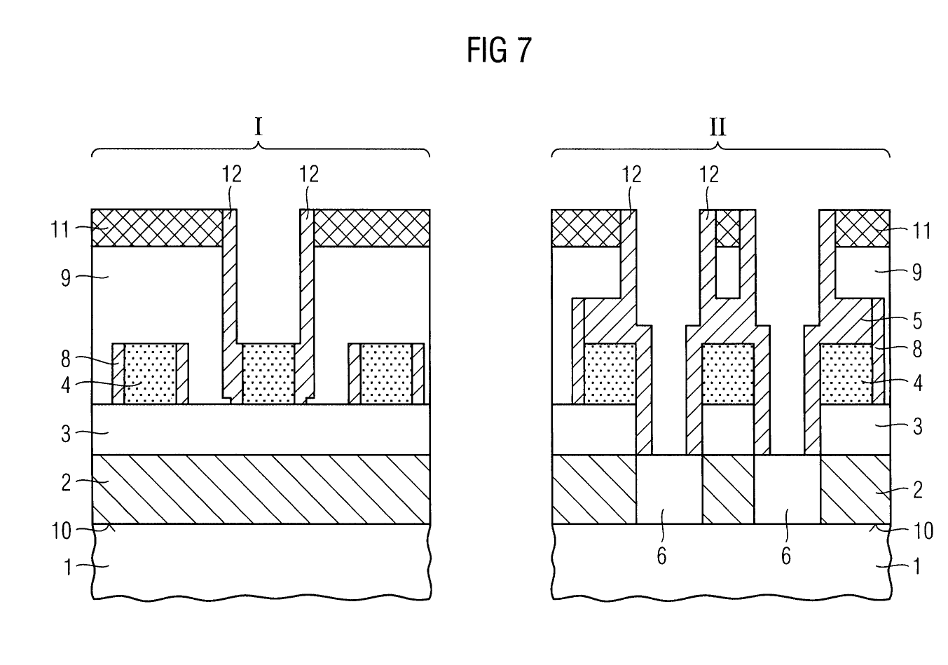

In the next step, optionally, an additional silicon nitride spacer 12 can be formed. This step can be omitted, when the first silicon nitride spacer 8 has a sufficient thickness. For example, the second silicon nitride spacer 12 is formed by a conventional spacer process. The resulting structure is shown in FIG. 7.

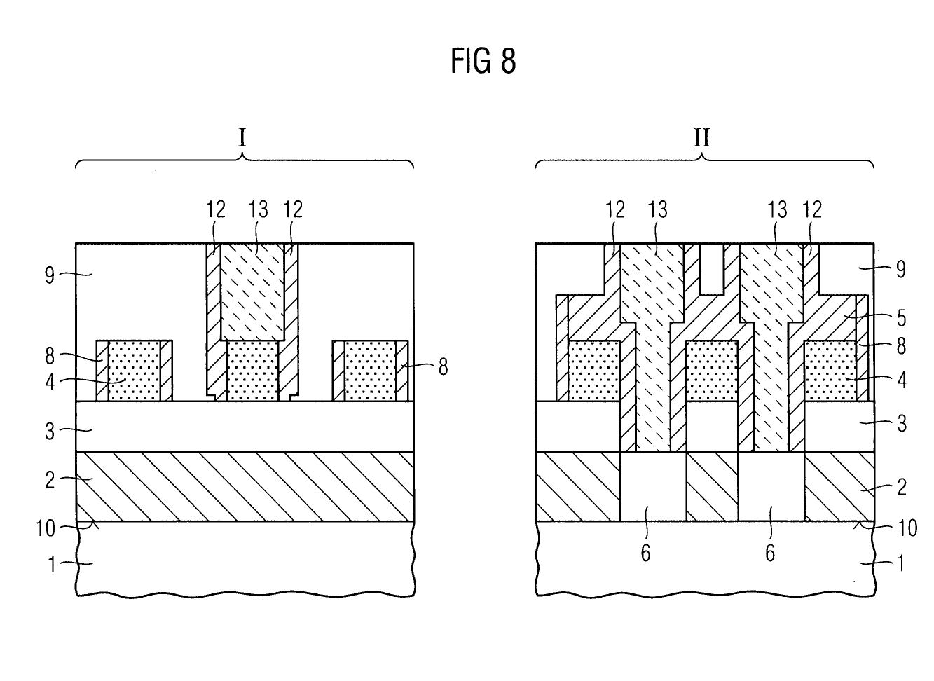

In the next step, the hard mask material 11 is removed from the surface and the capacitor contact openings and the support contact openings are filled with a conductive material 13. For example, on the polysilicon contacts 6, a thin liner, such as Ti, Co, or Ni is deposited. Then, an annealing step forms TiSi, CoSi, or NiSi. Thereafter, for example, tungsten is deposited to fill the capacitor contact openings and the support contact openings. Next, a CMP step is performed to obtain the structure shown in FIG. 8.

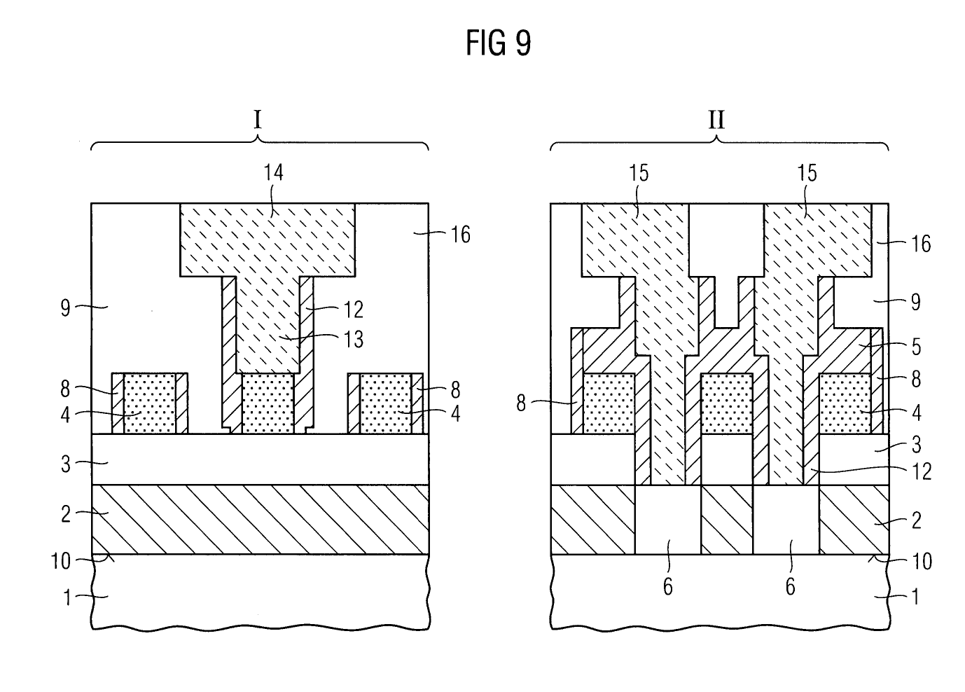

Thereafter, a further silicon dioxide layer 16 is deposited and openings for a landing pad in the peripheral portion I and for the contact pads in the array portions are defined by generally known methods. In particular, the corresponding openings are formed and the openings are filled with tungsten and, finally, a CMP method is performed to obtain the structure shown in FIG. 9.

As can be seen from FIG. 9, in the array portion II contact pads 15 are formed in the upper portion thereof. The contact pads 15 are connected with the poly-contacts 6 by the tungsten material forming the capacitor contacts. In the peripheral portion I, a landing pad 14 is provided at the same height as the contact pad 15 in the array portion. For example, the landing pad 14 can have a width of 1.7×F to 2.3×F (the width is measured perpendicularly to the direction of the M0 lines in a horizontal plane).

In the shown layout, depending on the design rules of the support portion, the next landing pad is, for example, positioned to be connected with every fourth line of the M0 metallization layer of the illustrated cross-sectional view. As a consequence, a relatively large landing pad is provided, without increasing the line width of the M0 metallization layer.

Thereafter, the memory device is completed by providing a storage capacitor on top of the contact pad 15. In particular, the storage capacitors are provided by forming a first capacitor electrode, which can have the shape of a cup or a cylinder, by providing a capacitor dielectric such as made of any suitable dielectric material, for example, SiO₂, or Si₃N₄, or others and by providing a second capacitor electrode 19. The whole memory device is covered with a silicon dioxide layer 20. Thereafter, a C1 contact to the landing pad 14 is formed by generally known methods. In particular, a contact opening is formed and filled with a TiN liner 21 and a tungsten filling 22. Since the C1 contact hole can be formed in the silicon dioxide layer 20 by etching silicon dioxide selectively with respect to the material of the landing pad the etching step is less critical. In addition, due to the huge landing pads, the overlay requirements of the C1 contact are extremely relaxed. Furthermore the resistance of the contact is not increased due to a bad overlay. Additionally, since due to the large landing pad, the diameter of the C1 contact can be increased, thus further decreasing the resistance of the C1 contact. For example, the C1 contact has a diameter of 150 to 170 nm in the upper portion thereof.

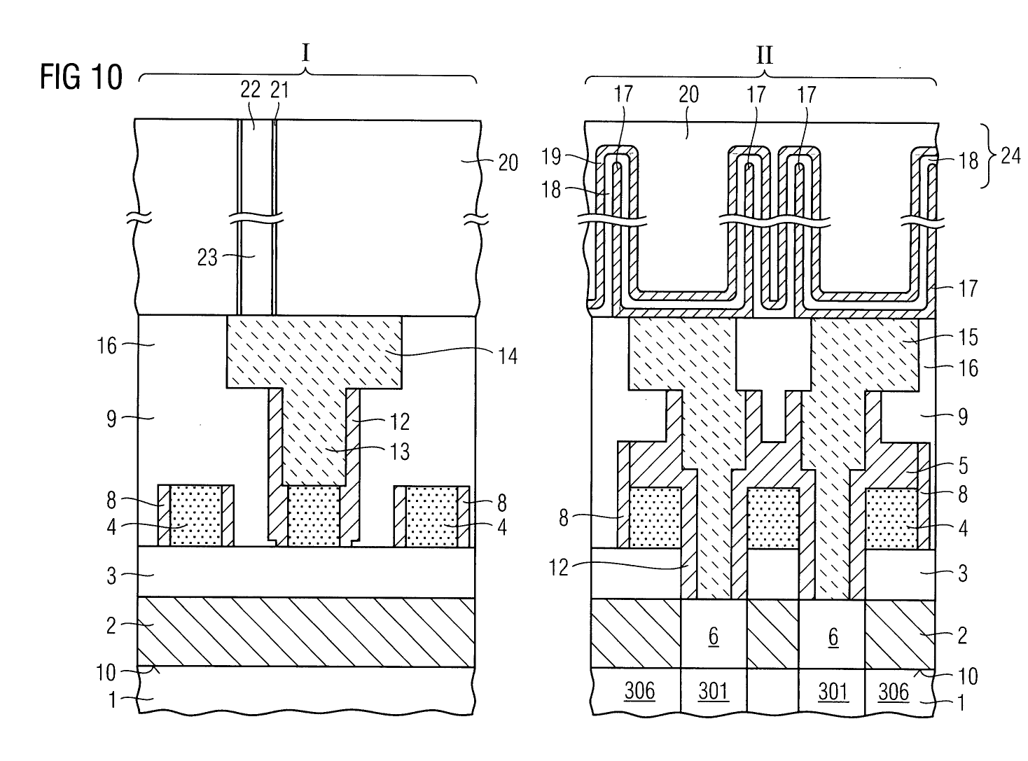

A cross-sectional view of the completed memory device is shown in FIG. 10. As can be seen from the right portion, the array portion has a storage capacitor, which is implemented as a stacked capacitor 24. The first capacitor electrode 17 of the storage capacitor is connected via the contact pad 15, the capacitor contact, and the polysilicon contact 6 to the first source/drain region 301 of the access transistor forming part of the memory cell. The first source/drain region 301 is formed in the semiconductor substrate 1. The second source/drain region 302 and the channel are disposed in the active area extending perpendicularly to the illustrated cross-section. These parts of the access transistor are not shown in this cross-sectional view. The first source/drain regions 301 are insulated from each other by isolation trenches 306.

Likewise in the peripheral portion, the C1 contact 23 is connected with the landing pad, which is connected with the line 4 of the M0 metallization layer. Although the silicon dioxide layer 20 has a thickness, which is determined by the height of the stacked capacitor, the etching of the C1 contact 23 is not critical since in the shown memory device a landing pad 14 is provided. The landing pad 14 has a large area, thereby simplifying a proper alignment and allowing for a relatively larger diameter of the C1 contact 23.

In addition, the landing pad 14 is positioned in a layer which is above the M0 metallization layer. As a consequence, the thickness of the material to be etched is decreased in comparison with the conventional memory device. As a consequence, the method of forming the C1 contact is further simplified.

The formation of the memory device according to the second embodiment of the present invention starts with a semiconductor substrate 1 as according to the first embodiment. On the surface 10 of the semiconductor substrate, first a BPSG (boron phosphorous silicate glass) layer 2 is deposited. Thereafter, optionally, a silicon nitride layer 27 can be deposited to provide an etch stopping layer.

In the BPSG layer 2 and the silicon nitride layer 27, contacts 6 made, for example, of polysilicon, are formed in the transistor array portion II, in the same manner as according to the first embodiment. Thereafter, a silicon dioxide layer 3 is deposited. In the next step, the M0 metallization layer is defined in the same manner as according to the first embodiment. The lines of the M0 metallization layer are covered by a silicon nitride cap layer and the side walls of the M0 metallization layer lines are covered by a silicon nitride spacer 8. For example, the silicon nitride spacer 8 is formed by a conventional spacer process.

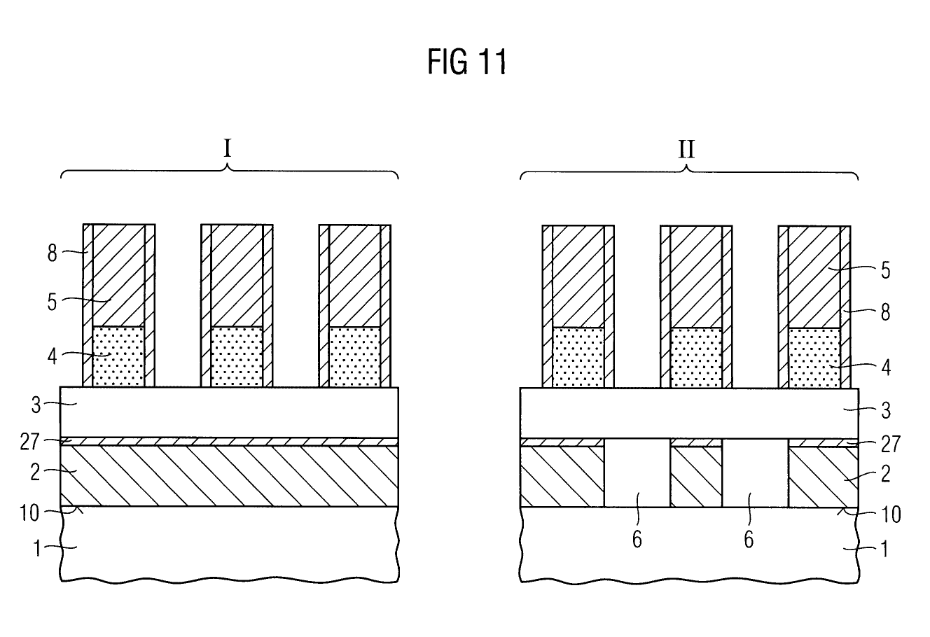

The resulting structure is shown in FIG. 11.

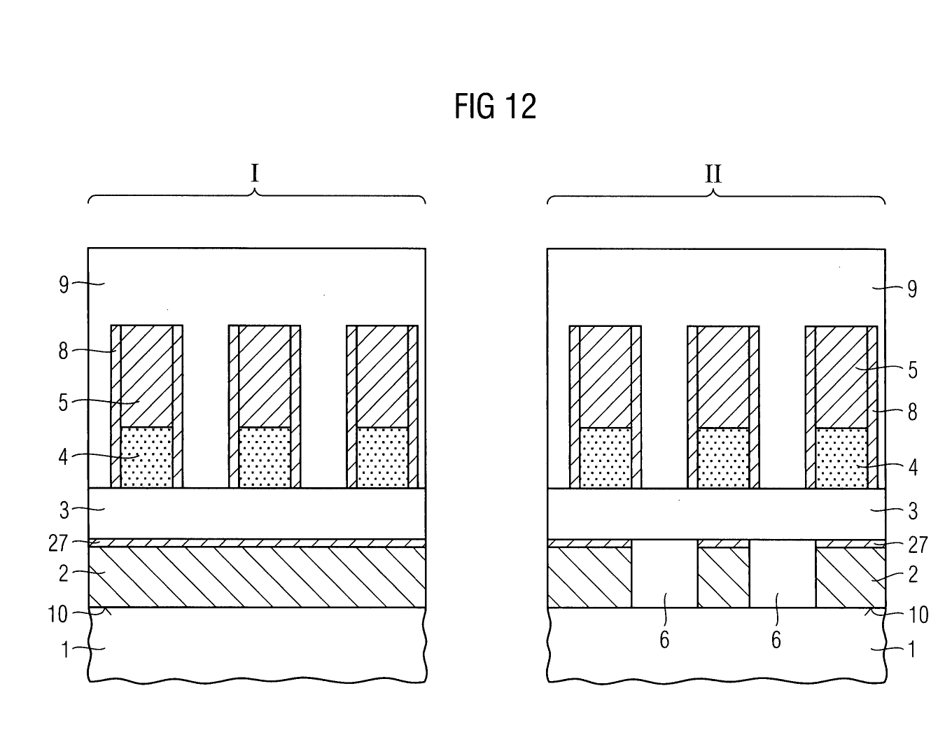

Thereafter, a silicon dioxide layer 9 is deposited over the whole semiconductor substrate and a CMP step is performed to obtain the structure shown in FIG. 12.

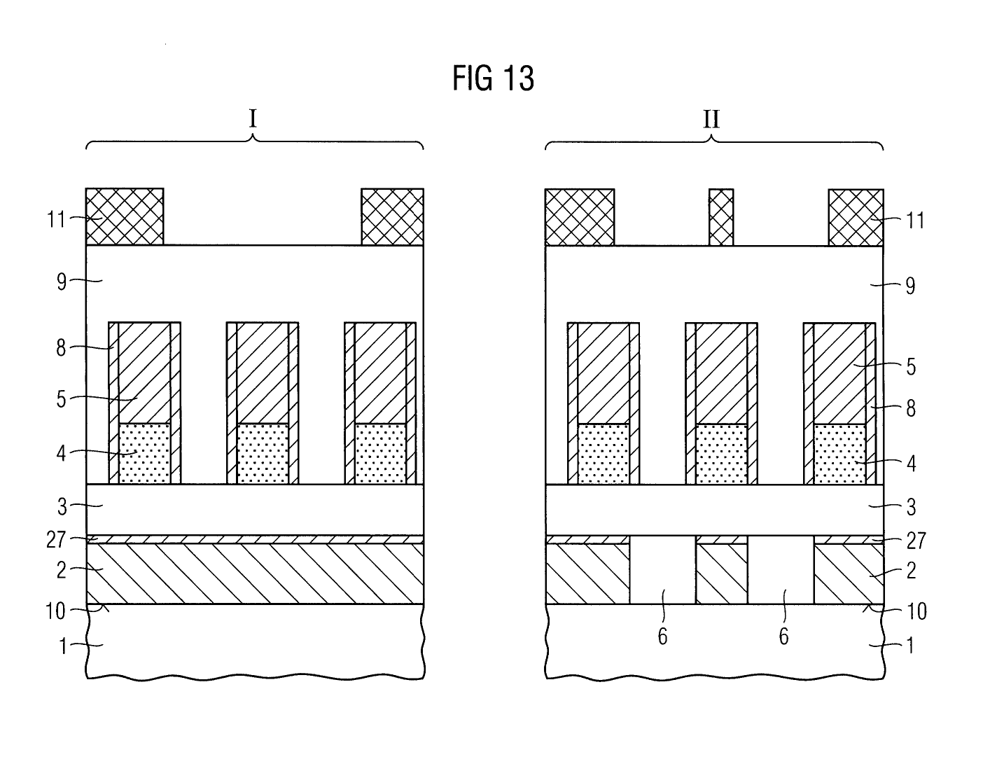

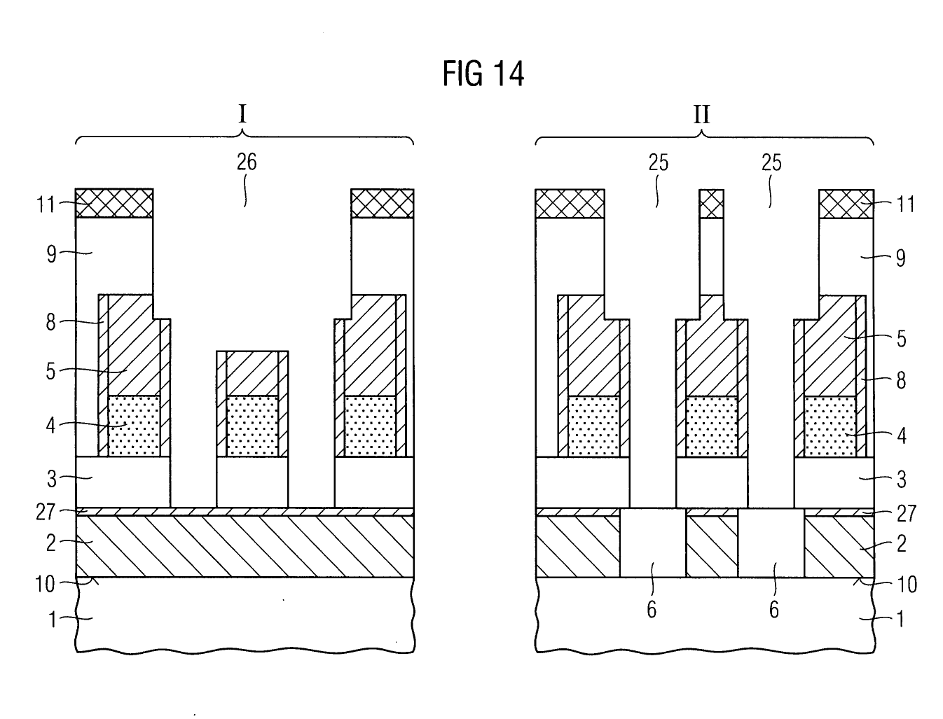

Then, a mask layer 11, in particular, a poly-silicon hard mask layer is deposited and photolithographically patterned in the manner as shown in FIG. 13. The mask layer 11 is formed of a resist material, for example, a photoresist material. Next, an etching forms capacitor contact openings 25 in the array portion II and support contact openings 26 in the peripheral portion I. For example, this etching step etches silicon dioxide relatively substantially selectively with respect to silicon nitride. Nevertheless, since the central portion of the opening 26 is exposed by this etching, a considerable portion of the silicon nitride cap 5 covering the central line 4 is etched. The resulting structure is shown in FIG. 14. As can be seen from FIG. 14, in the array portion II and the peripheral portion I, by this etching, part of the silicon nitride layers 5, 8 are etched.

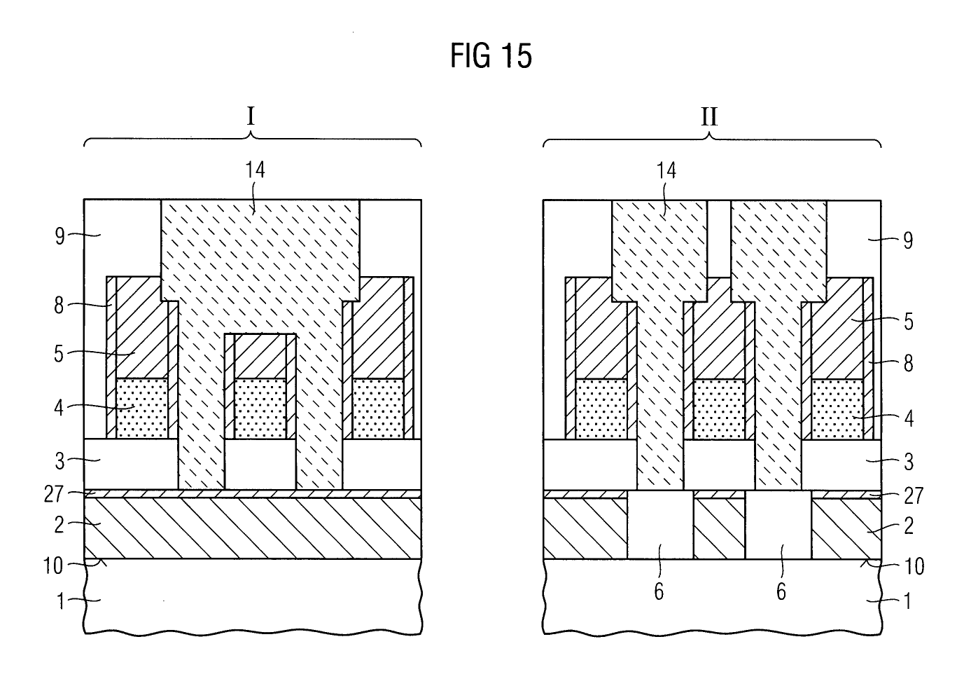

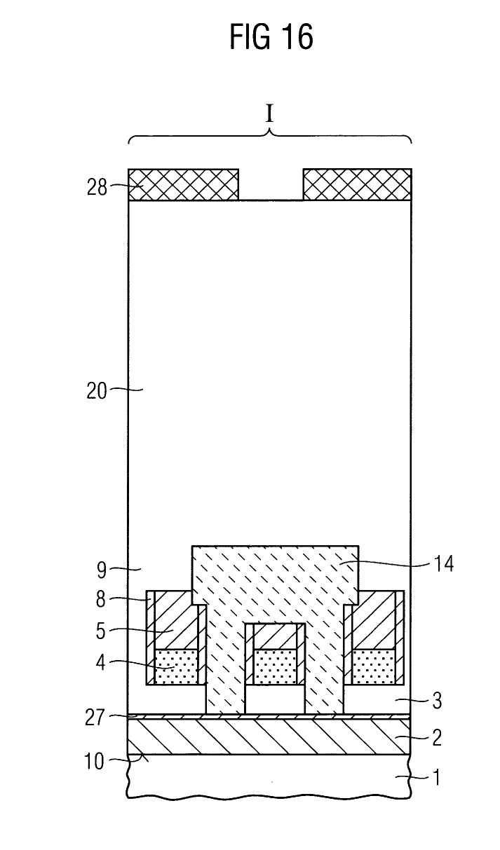

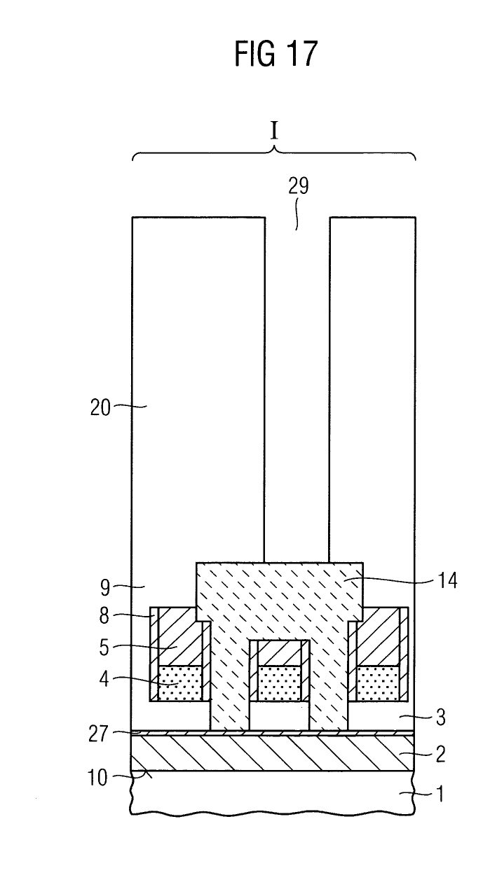

Next, the openings 25 and 26 are filled with a material which will not be attacked by the etching step which will be described with reference to FIG. 17. For example, the openings are filled with polysilicon or tungsten. After this step, a CMP step is performed to obtain the structure shown in FIG. 15. For example, in the peripheral portion, a support contact pad 14 is formed. The support contact pad 14 has a width of 3,5×F to 4×F. The width is measured parallel to the substrate surface. For example, the support contact pad 14 can have a width so as to overlap several lines of the M0 wiring layer. Such a large width of the support contact pad 14 is not critical with respect to shorts, since according to the design rules for the C1 contacts, neighboring lines are not hit by different C1 contacts in the depicted cross-sectional view.

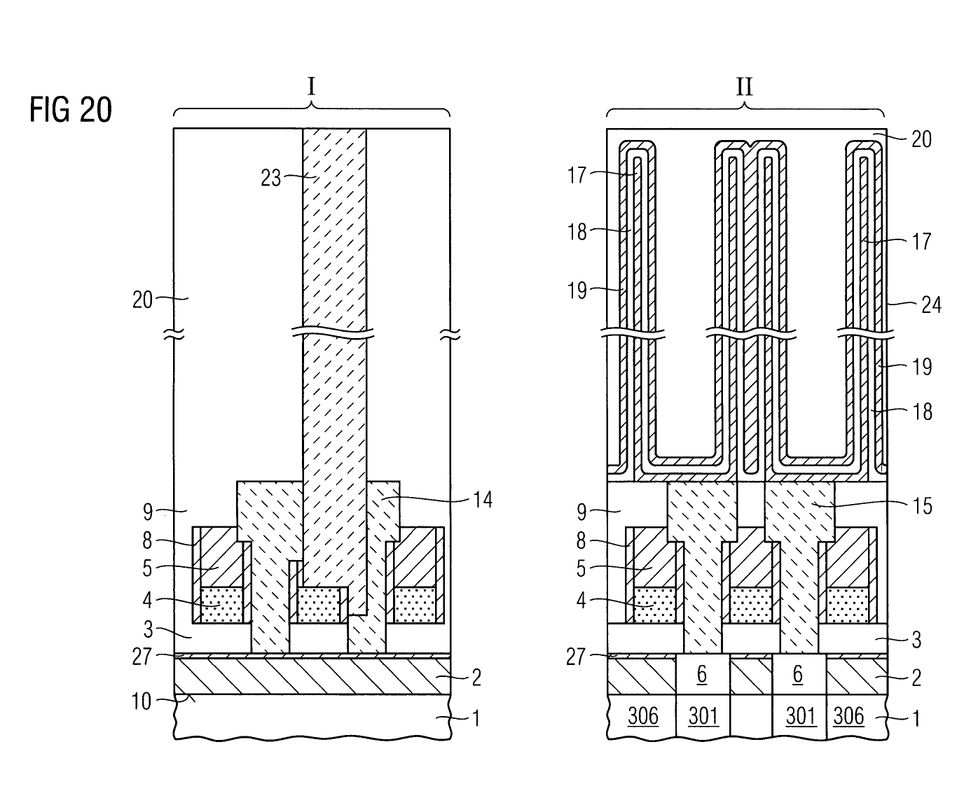

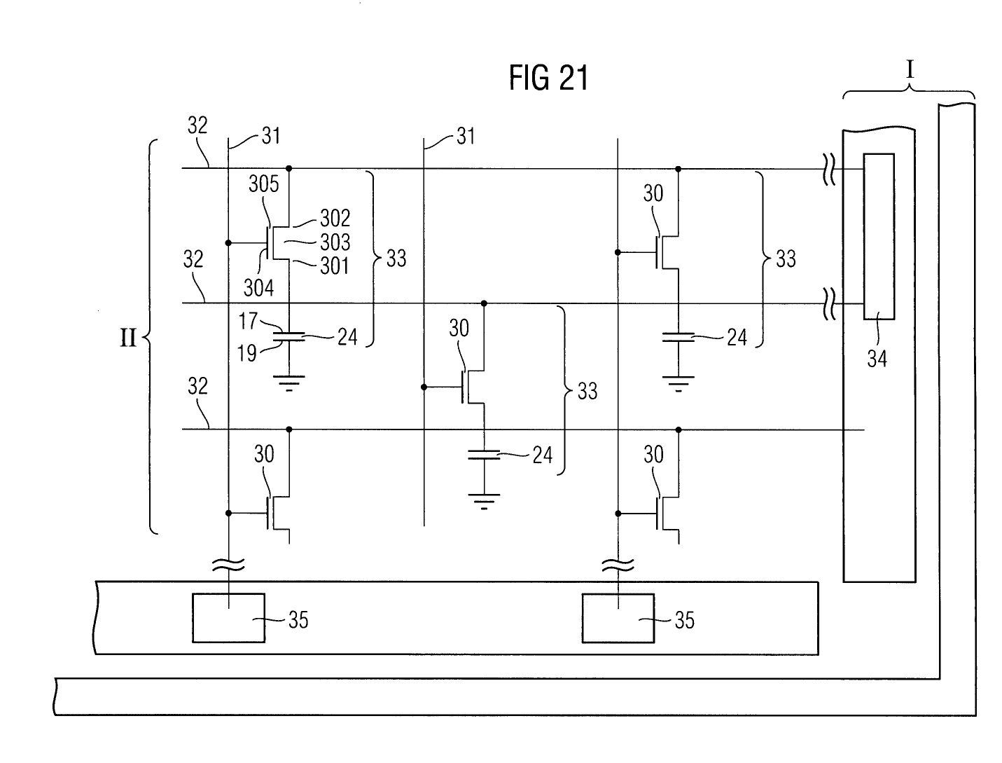

In the following, the connection of the C1 contacts to the support contact pad 14 will be described in detail. In the array portion II, a capacitor has been formed, as will be shown in FIG. 20. Thereafter, the whole substrate surface is covered with a thick silicon dioxide layer having a thickness of approximately 3 μm. During the subsequent steps, the array portion II is covered with a hard mask layer 28.

For defining the C1 contacts, a hard mask layer 28, which is, for example, made of polysilicon, is deposited and patterned using a mask for defining a C1 contact. In the next step, the C1 contact opening 29 is etched by performing an anisotropic etching step which stops on the support contact pad 14. The resulting structure is shown in FIG. 17.

Thereafter, the material 13 of the support contact pad 14 is etched selectively with respect to silicon nitride. Due to the presence of the silicon nitride etching stop layer 27, an over-etching will not cause shorts and, thus, is not critical.

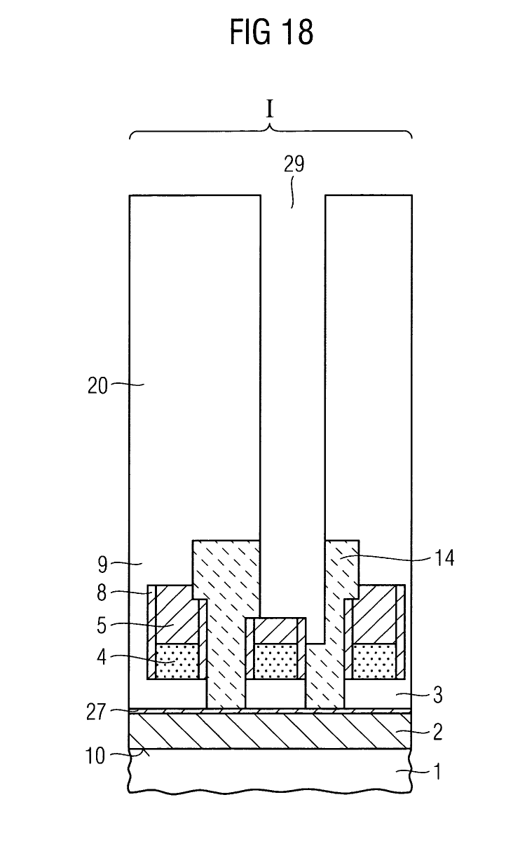

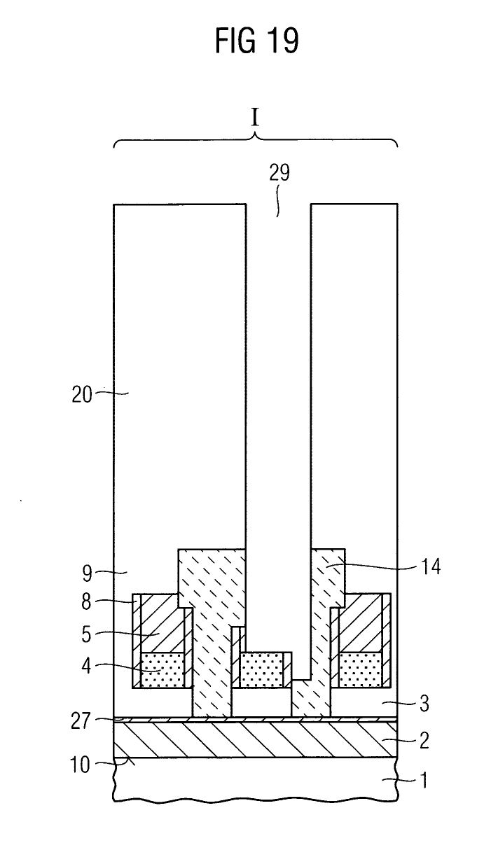

The resulting structure is shown in FIG. 18. Thereafter, the silicon nitride is etched selectively with respect to the material 13 of the support contact pad 14. The resulting structure is shown in FIG. 19.

Thereafter, the opening 29 is filled with a conductive material, in particular, a TiN liner (not shown) and a tungsten filling 23. The resulting structure is shown in FIG. 20.

The right hand part of FIG. 20 also shows the array portion comprising the storage capacitors 24. As can be seen, the memory cells in the array portion II have been completed by defining a first capacitor electrode 17 in contact with a contact pads 15, a dielectric layer 18, and the second capacitor electrode 19. Two contact pads are connected with the first source/drain regions 301 forming part of the access transistors. The first source/drain regions 301 are formed in the semiconductor substrate 1 and are insulated from each other by isolation trenches 306.

As can be taken from the foregoing, the etching the C1 contact opening 21 across the silicon dioxide layer 20 is better controlled as a selective etching stopping on the support contact pad 14. As a consequence, the conventional time-controlled etching is replaced by an etching that automatically stopped as soon as the support contact pad 14 is reached. Thereby, unwanted shorts are avoided. Furthermore, for a technology with a half pitch (F) of 90 nm, the M0 line width is decreased from 220 nm to 90 nm, since a large landing area in the M0 wiring is no longer necessary.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCES

1 semiconductor substrate
2 BPSG layer
3 SiO₂ layer
4 M0 wiring layer
5 Si₃N₄ cap
6 polysilicon contact
7 mask layer
8 Si₃N₄ spacer
9 SiO₂ layer
10 substrate surface
11 hard mask
12 Si₃N₄ spacer
13 conductive filling
14 support contact pad
15 array contact pad
16 SiO₂ layer
17 first capacitor electrode
18 capacitor dielectric
19 second capacitor electrode
20 SiO₂ layer
21 TiN liner
22 tungsten filling
23 C1 contact
24 storage capacitor
25 capacitor contact opening
26 support contact opening
27 Si₃N₄ etching stop layer
28 hardmask layer
29 C1 contact opening
30 transistor
301 first source/drain region
302 second source/drain region

What is claimed is:

1. A memory device, comprising:
an array of memory cells, the memory cells being at least partially formed in a semiconductor substrate having a surface, each of the memory cells including an access transistor having a first and a second source/drain region, a channel disposed between the first and second source/drain regions, and a gate electrode electrically insulated from the channel and adapted to control the conductivity of the channel, the access transistor being at least partially formed in the semiconductor substrate;
a storage capacitor for storing an information, the storage capacitor being adapted to be accessed by the access transistor, the storage capacitor having at least first and second storage electrodes and at least a capacitor dielectric disposed between the first and second storage electrodes, wherein each of the first and second storage electrodes is disposed above the substrate surface, a contact between the first storage electrode and the first source/drain region of the access transistor formed by a capacitor contact and a contact pad, the capacitor contact extending from the substrate surface and connecting the substrate surface with the contact pad, the contact pad being adjacent to the first capacitor electrode;
a peripheral portion having peripheral circuitry for controlling a read and a write operation of the memory cell array, the peripheral circuitry being connected with the memory cell array via lines;
a first wiring layer provided in the memory cell array and in the peripheral portion, the first wiring layer having first lines;
a contact layer lying above the first wiring layer, the contact layer being provided in the memory cell array in the peripheral portion; and
a first insulating layer disposed above the contact layer, the contact layer having contact pads in the memory cell array, the contact pads being insulated from the first wiring layer, the contact layer having contact structures in the peripheral portion.

2. The memory device of claim 1, wherein the contact structures in the peripheral portion are connected with the first lines of the first wiring layer, thereby forming landing pads.

3. The memory device of claim 1, wherein the contact structures are made of a material, which can be etched selectively with respect to the material of the first insulating layer.

4. The memory device of claim 3, further comprising:
a second insulating layer disposed above the first wiring layer, wherein the material of the second insulating layer can be etched selectively with respect to the material of the contact structures.

5. The memory device of claim 3, wherein the contact structures in the peripheral portion are made of polysilicon or tungsten.

6. The memory device of claim 1, wherein the contact structures in the peripheral portion have a width of 1.7×F to 2.3×F, the width being measured parallel to the substrate surface and F denoting the minimum lithographic feature size.

7. A method of forming a memory device, comprising:
providing a semiconductor substrate having a surface;
providing an array of access transistors, each of the access transistors including a first and a second source/drain regions, a channel disposed between the first and second source/drain regions and a gate electrode electrically insulated from the channel and adapted to control the conductivity of the channel, each of the access transistors being at least partially formed in the semiconductor substrate;
providing a peripheral portion including peripheral circuitry, the peripheral portion being at least partially formed in the semiconductor substrate;
providing a first contact layer including connected with the first source/drain regions, the contacts being electrically insulated from each other;
providing a first dielectric layer on the first contact layer;
providing a first wiring layer in the array portion and the peripheral portion, the first wiring layer having first lines, the first lines being covered by a wiring insulation layer in the transistor array portion, the first lines of the peripheral portion being uncovered;
providing a first insulating layer in the array portion and the peripheral portion, the material of the insulating layer being different from the wiring insulation layer;
providing capacitor contact openings in the array portion, the openings contacting the contacts of the first contact layer;
providing support contact openings in the peripheral portion, the support contact openings contacting the first lines;
providing a conducting material in the capacitor contact openings and in the support contact openings to form capacitor contacts in the array portion and support contacts in the peripheral portion, the support contacts serving as landing pads; providing a second insulating layer on the first insulating layer having the capacitor contacts and the support contacts;
defining contact pads in the array portion and contact structures in the peripheral portion, the contact pads contacting the capacitor contacts and the contact structures contacting the support contacts;
providing a first storage electrode, a storage dielectric, and a second storage electrode, the first storage electrode contacting one of the contact pads, thereby forming a storage capacitor;
providing a third insulating layer; and
forming a contact in the third insulating layer, the contact being connected with one of the contact structures in the peripheral portion.

8. A method of forming a memory device, comprising:
providing a semiconductor substrate having a surface;
providing an array of access transistors, each of the access transistors including a first and a second source/drain regions, a channel disposed between the first and second source/drain regions and a gate electrode electrically insulated from the channel and adapted to control the conductivity of the channel, each of the access transistors being at least partially formed in the semiconductor substrate;
providing a peripheral portion including peripheral circuitry, the peripheral portion being at least partially formed in the semiconductor substrate;
providing a first contact layer including contacts connected with the first source/drain regions, the contacts being electrically insulated from each other;
providing a first dielectric layer on the first contact layer;
providing a first wiring layer in the array portion and the peripheral portion, the first wiring layer including first lines, the first lines being covered by a wiring insulation layer in the transistor array portion and in the peripheral portion;
providing a first insulating layer in the array portion and the peripheral portion, the material of the insulating layer being different from the wiring insulation layer;
providing capacitor contact openings in the array portion, the openings contacting with the contacts of the first contact layer;
providing support contact openings in the peripheral portion, the support contact openings being adjacent to the wiring insulation layer covering the first lines;
providing a conducting material in the capacitor contact openings and in the support contact openings thereby forming contact pads in the array portion and contact structures in the peripheral portion;
providing a first storage electrode, a storage dielectric and a second storage electrode, the first storage electrode contacting one of the contact pads, thereby forming a storage capacitor;
providing a third insulating layer;
etching a contact hole in the third insulating layer, the contact hole being connected with one of the contact structures in the peripheral portion;
selectively etching the contact structures in the peripheral portion with respect to a wiring insulation layer;
selectively etching the wiring insulation layer with respect to the material of the contact structures; and
filling the resulting opening with a conductive material to form a contact connected with one of the first lines.

9. The method of claim 8, wherein etching a contact hole includes etching the material of the third insulating layer selectively with respect to the material of the contact structures.

10. The method of claim 8, further comprising:
providing an etch stop layer on the surface of the first contact layer.
